(19) United States
(12) Patent Application Publication
(10) Pub. No.: US 2015/0301088 A1
(43) Pub. Date: Oct. 22, 2015

(54) CURRENT MEASUREMENT DEVICE AND CURRENT MEASUREMENT METHOD

(71) Applicant: FUJITSU LIMITED, Kawasaki-shi (JP)

(72) Inventors: Hiromitsu Soneda, Atsugi (JP); Fumio Takei, Isehara (JP)

(21) Appl. No.: 14/642,708

(22) Filed: Mar. 9, 2015

(30) Foreign Application Priority Data
Apr. 21, 2014 (JP) 2014-087066

(51) Int. Cl. G01R 15/20; G01R 1/04

(52) U.S. Cl. CPC G01R 15/20; G01R 1/0408

(57) ABSTRACT

A current measurement device is provided which includes a casing configured to surround a cable and a magnetic sensor. The magnetic sensor is configured to be movable along the periphery of the cable within the casing and to output an output signal varying according to a current value of a current flowing through the cable.

### CROSS-REFERENCE TO RELATED APPLICATION

This application is based upon and claims the benefit of priority of the prior Japanese Patent Application No. 2014-087066, filed on Apr. 21, 2014, the entire contents of which are incorporated herein by reference.

### FIELD

The embodiments discussed herein are related to a current measurement device and a current measurement method.

### BACKGROUND

Current measurement devices for measuring a current flowing through a cable include clamp-type current measurement devices. A clamp-type current measurement device includes a pair of semicircular cores which clamps a cable, and is a device for measuring a current in the cable based on an induced voltage generated in a coil wound around the core. This structure makes it possible to easily measure a current by clamping a cable with the pair of cores, and provides a convenience to an operator.

However, in the case where a cable includes two wires through which their respective currents flow in opposite directions, magnetic fields generated around the respective wires are prone to be canceled by the cores. Accordingly, an induced current flowing through the coil wound around the core is reduced, and it is difficult to accurately measure a current using a clamp-type current measurement device. A similar problem also occurs in the case where a cable contains a ground wire as well as two wires.

In such a case, to accurately measure a current in each wire, each wire preferably is singly clamped with the cores separately by, for example, pulling each wire out of the cable.

However, this places the burden of processing the cable on an operator. Further, in the case where the cable is the property of a client, processing the cable will damage the client's equipment. Accordingly, even processing the cable is not performed.

Note that techniques relating to the present application are disclosed in Japanese Laid-open Patent Publication Nos. 2013-88349, 2007-78668, and 2008-275558.

### SUMMARY

One aspect of the disclosure below provides a current measurement device including: a casing configured to surround a cable; and a magnetic sensor configured to be movable along a periphery of the cable within the casing and to output an output signal varying according to a current value of a current flowing through the cable.

Moreover, another aspect of the disclosure provides a current measurement method including: while moving a magnetic sensor configured to output an output signal varying according to a current value of a current flowing through a cable along a periphery of the cable, measuring the current value with the magnetic sensor; and determining a largest value of the current value around the cable to be the current value.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a view illustrating principles of a clamp-type current measurement device;

FIG. 2 illustrates results of a simulation of a magnetic field generated around a cable containing two wires;

FIG. 3 is a schematic perspective view of a model used in the simulation of FIG. 2;

FIG. 4 illustrates results of a simulation of a magnetic flux density around the two wires;

FIG. 5 is a schematic cross-sectional view for explaining the sensing direction of a magnetic sensor;

FIG. 6 illustrates the magnetic sensor overlaid on the results of the magnetic field simulation explained with reference to FIG. 2;

FIG. 7 is an external view of a current measurement device according to a first embodiment;

FIG. 8 is an external view illustrating the current measurement device according to the first embodiment with a movable portion open;

FIG. 9 is a cross-sectional view of the current measurement device according to the first embodiment;

FIG. 10 is a cross-sectional view of guides and surroundings thereof in the first embodiment;

FIGS. 11A to 11D are cross-sectional views illustrating other examples of the cross-sectional shape of the guide in the first embodiment;

FIG. 12 is another cross-sectional view of the current measurement device according to the first embodiment;

FIG. 13 is a general perspective view illustrating a rotating plate and a first gear in the first embodiment;

FIG. 14 is a schematic diagram illustrating the positional relationship between the magnetic field generated around the cable and the magnetic sensor in the first embodiment;

FIG. 15 is a graph illustrating the relationship between the traveled angle of the magnetic sensor and the magnitude of an output signal from the magnetic sensor in the first embodiment;

FIG. 16 is a cross-sectional view illustrating an inside of a body portion of the magnetic sensor according to the first embodiment;

FIG. 17 is a functional block diagram of a measuring unit in the first embodiment;

FIG. 18 is a flowchart illustrating a current measurement method according to the first embodiment;

FIG. 19 is a perspective view of the current measurement device according to the first embodiment in which a notification unit is provided on the casing;

FIG. 20 is a perspective view of spacers used in a second embodiment;

FIG. 21 is a perspective view for explaining how to use the spacers according to the second embodiment;

FIG. 22 is a perspective view for explaining a spacer according to another example of the second embodiment;

FIG. 23 is a perspective view of a current measurement device according to a third embodiment;

FIG. 24 is a perspective view of a current measurement device according to a fourth embodiment;

FIG. 25 is a perspective view of a rotating plate according to the fourth embodiment;

FIG. 26 is a cross-sectional view illustrating a peripheral edge of a rotating plate according to a fifth embodiment and the vicinity thereof;

FIG. 27 is a cross-sectional view illustrating a peripheral edge of a rotating plate according to a sixth embodiment and the vicinity thereof;

FIG. 28 is a perspective view of a current measurement device according to a seventh embodiment;

FIG. 29 is a perspective view of a rotating plate according to a first modification;

FIG. 30 is a perspective view of a rotating plate according to a second modification;

FIG. 31 is a perspective view illustrating the second modification with a rotating plate being removed from a hollow container;

FIG. 32 is a perspective view of a rotating plate according to a third modification.

### DESCRIPTION OF EMBODIMENTS

Researches performed by the inventors of the present application will be described prior to the description of embodiments.

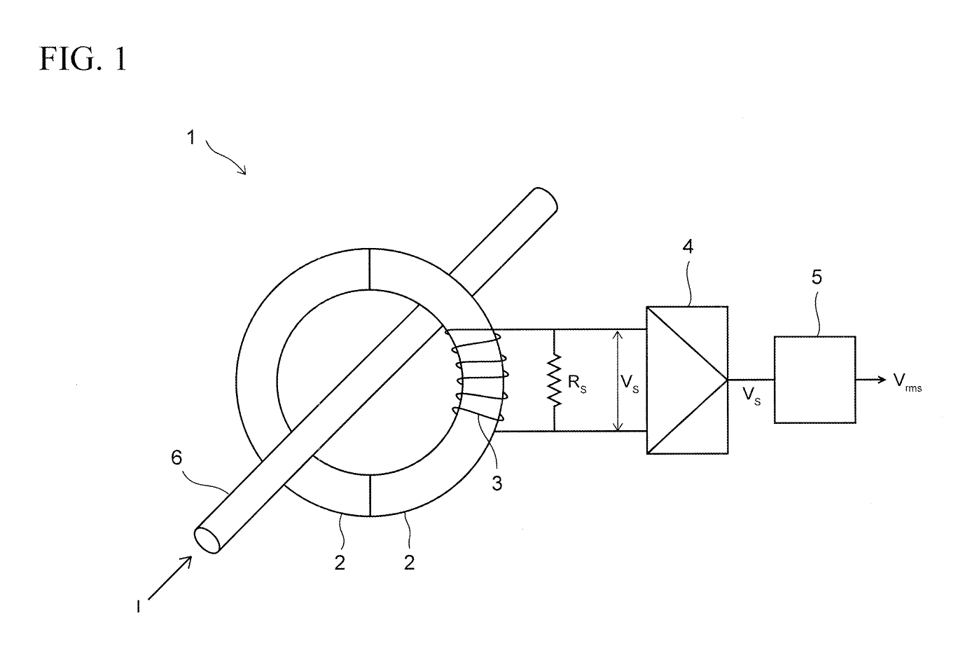

FIG. 1 is a view illustrating principles of a clamp-type current measurement device.

First, a description will be made for the case where a current value of an alternating current I flowing through a solid-wire cable 6 is measured using a clamp-type current measurement device 1.

The clamp-type current measurement device 1 includes a pair of semicircular cores 2 surrounding the cable 6 and a coil 3 wound around the core 2.

The magnetic flux generated around the cable 6 by the alternating current I is converged by the cores 2. This causes an induced current to flow through the coil 3. The induced current flows through a resistor R_{S} connected in parallel with the coil 3, and an induced electromotive force V_{S} is generated in the resistor R_{S}.

The induced electromotive force V_{S} is amplified in a differential amplifier 4 and then inputted to an RMS (Root Mean Square) converter 5 in a subsequent stage. The RMS converter 5 converts the induced electromotive force V_{S}, which is an alternating voltage, to an effective value Vᵣₘₛ thereof, and outputs the effective value Vᵣₘₛ to an outside.

This configuration allows the magnetic flux around the cable 6 to be converged by the cores 2 even when the alternating current I flowing through the cable 6 is weak. Accordingly, an adequately large induced electromotive force V_{S} is generated in the coil 3, and the alternating current I may be measured based on the induced electromotive force V_{S}.

As described above, in the case where the cable 6 is a solid wire, it is easy to measure the alternating current I using the clamp-type current measurement device 1. However, in the case where the cable 6 contains a plurality of wires, it is difficult to measure an alternating current as described below.

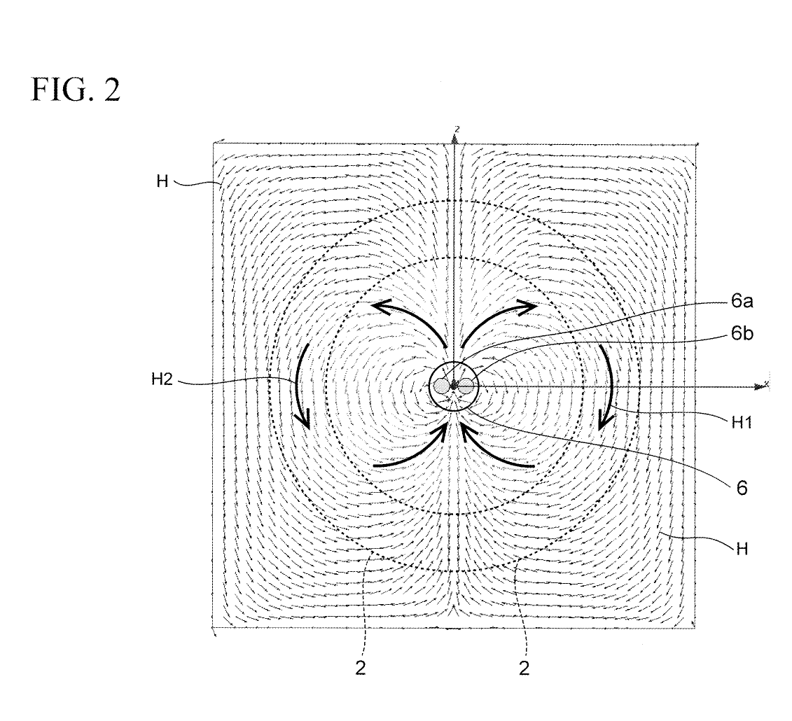

FIG. 2 illustrates results of a simulation of a magnetic field H generated around a cable 6 containing two wires 6a and 6b.

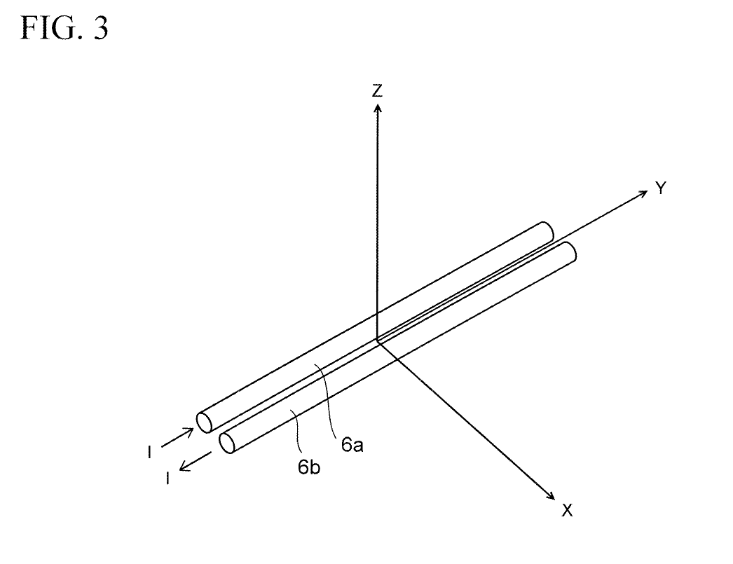

Moreover, FIG. 3 is a schematic perspective view of a model used in the simulation.

As illustrated in FIG. 3, in this simulation, direct currents I flow through the wires 6a and 6b in opposite directions, respectively. Note that the magnitude of the direct current I is 1 ampere.

Further, in an XYZ Cartesian coordinate system, the Y axis is oriented parallel to the wires 6a and 6b, and the Z axis is oriented normal to the plane containing the wires 6a and 6b. Further, the X axis is oriented perpendicular to each of the Y axis and the Z axis.

In this case, as illustrated in FIG. 2, there are generated a magnetic field H1 which curls clockwise and a magnetic field H2 which curls counterclockwise. These magnetic fields H1 and H2 are canceled by each other within the cores 2. Accordingly, compared to the case of FIG. 1, the magnetic flux passing through the cores 2 decreases, and it is very difficult to measure the currents using the clamp-type current measurement device 1.

Accordingly, the inventors of the present application study the possibility of using a magnetic sensor such as a GMR (Giant Magneto Resistive) element rather than the cores 2 to measure the currents flowing through the wires 6a and 6b in opposite directions, respectively.

In a measurement of the currents using a magnetic sensor, it is desired that magnetic fields generated around the respective wires 6a and 6b are strong enough to be detectable by the magnetic sensor.

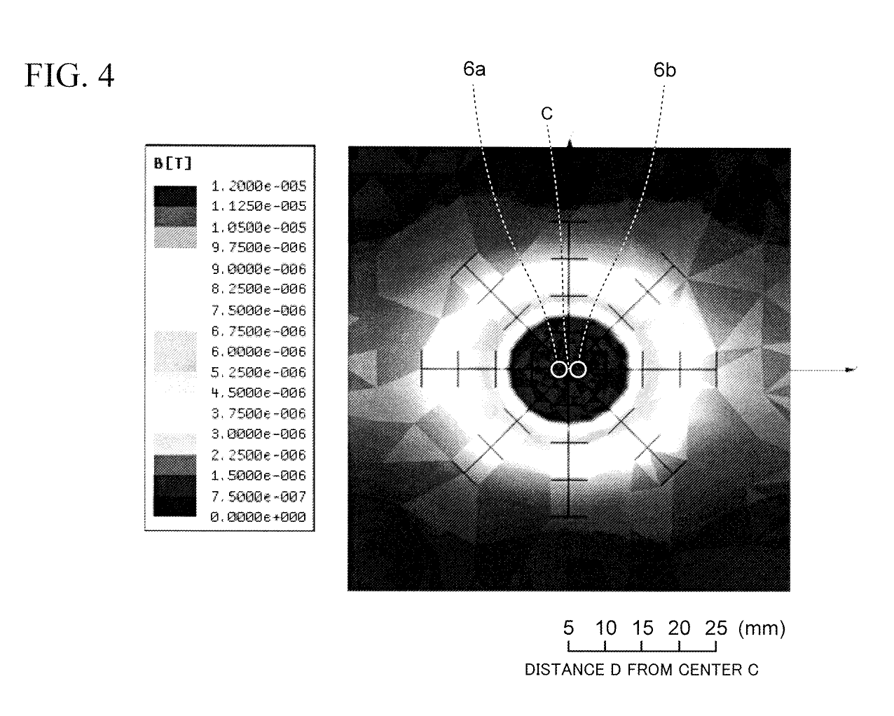

FIG. 4 illustrates results of a simulation of a magnetic flux density around the wires 6a and 6b. Note that a model used in the simulation is the same as that explained with reference to FIG. 3.

The results of the simulation of the magnetic flux density is approximately 6 ρT at a position where the distance D measured from a center C between the wires 6a and 6b is 10 mm, and that the magnetic flux density is 3 ρT at a position where the distance D is 15 mm. Magnetic flux densities at this level may be detected by a magnetic sensor such as a GMR element or an MI (Magneto-Impedance) element.

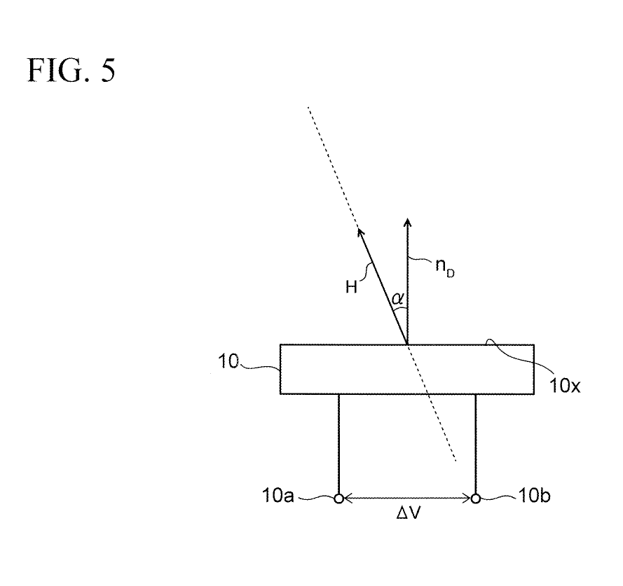

However, these magnetic sensors have sensing directions. The sensitivity of such a magnetic sensor may decrease depending on the direction of a magnetic field. This will be explained with reference to FIG. 5.

FIG. 5 is a schematic cross-sectional view for explaining the sensing direction of a magnetic sensor.

This magnetic sensor 10 includes a first terminal 10a and a second terminal 10b. A potential difference ΔV varying according to the intensity of a magnetic field H develops between the terminals 10a and 10b. The potential difference ΔV is outputted as an output signal SΔ_{V}.

The magnitude of the output signal SΔ_{V} depends on the orientation of the magnetic sensor 10 in a magnetic field H.

Hereinafter, the sensing direction n_{D} of the magnetic sensor 10 is defined as the direction of the magnetic field H in which the output signal SΔ_{V} becomes maximum. According to this definition, the output signal SΔ_{V} becomes maximum when the angle α between the magnetic field H and the sensing direction n_{D} is 0°. Moreover, the output signal SΔ_{V} monotonically decreases as the angle α increases.

Note that the sensing direction n_{D} is often the same as a normal direction to a surface 10x of the magnetic sensor 10, depending on the manufacturer of the magnetic sensor 10. In such a case, the output signal SΔ_{V} becomes maximum when the magnetic field H perpendicularly passes through the surface 10x.

Next, a position is considered at which the output signal SΔ_{V} from the magnetic sensor 10 becomes maximum as described above in the magnetic field H explained with reference to FIG. 2.

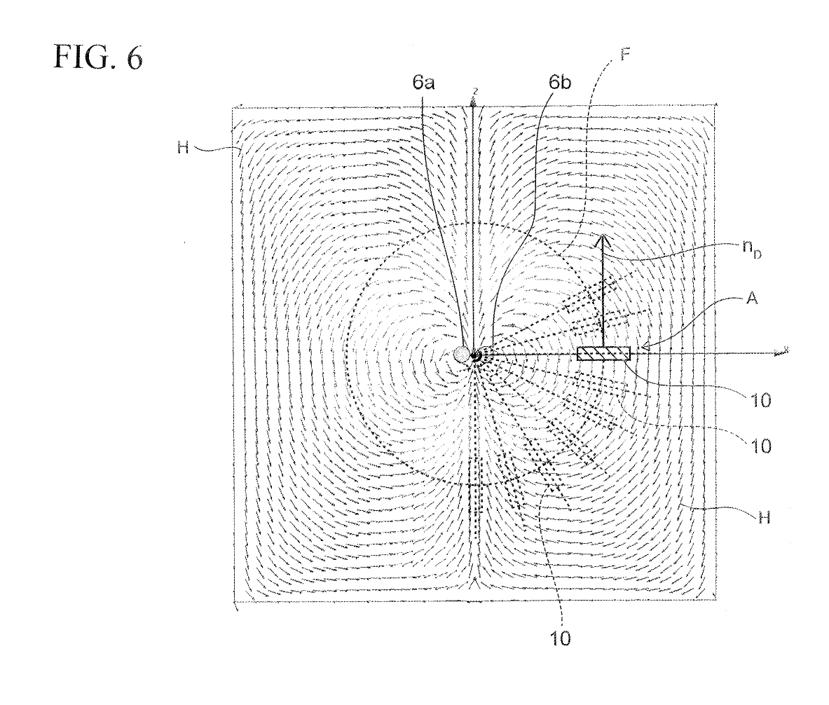

FIG. 6 illustrates the magnetic sensor 10 overlaid on the results of the magnetic field simulation explained with reference to FIG. 2.

FIG. 6 is based on the assumption that a circle F is set which is centered at the center between the wires 6a and 6b, and that the magnetic sensor 10 is provided at a plurality of points on the circle F with the sensing direction n_{D} being directed tangential to the circle F.

In that case, the sensing direction n_{D} becomes parallel to the magnetic field H at point A, where the output signal SΔ_{V} from the magnetic sensor 10 becomes maximum.

Accordingly, if point A is found among the plurality of points on the circle F, and the magnetic sensor 10 is fixed at point A, the magnetic field H may be detected with high sensitivity using the magnetic sensor 10. Thus, the values of currents flowing through the wires 6a and 6b may be measured with high accuracy based on the output signal SΔ_{V}.

Hereinafter, embodiments based on the above-described findings will be described.

### First Embodiment

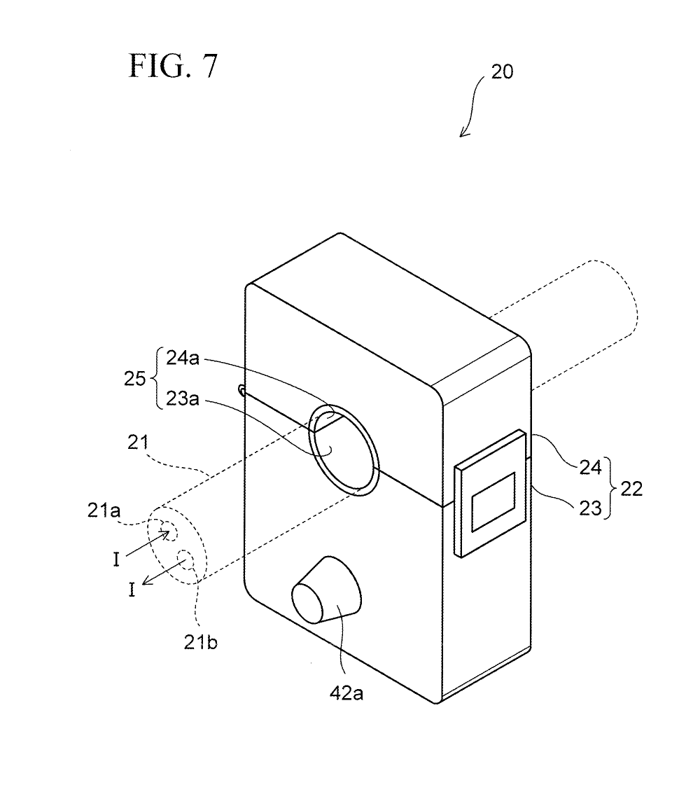

FIG. 7 is an external view of a current measurement device according to the present embodiment.

This current measurement device 20 is intended to measure a current flowing through a cable 21, and includes a casing 22 surrounding the cable 21.

The casing 22 includes a body portion 23 and a movable portion 24 connected to the body portion 23 to be openable and closable. When the movable portion 24 is closed, the cable 21 is clamped between the body portion 23 and the movable portion 24.

The structure of the cable 21 to be measured is not particularly limited. The following description is based on the assumption that the cable 21 contains two wires 21a and 21b and that alternating currents I having equal magnitudes flow through the wires 21a and 21b in opposite directions, respectively. A measurement according to the present embodiment may also be performed on the cable 21 containing a ground wire as well as the two wires 21a and 21b.

Further, the material of the casing 22 is also not particularly limited, and the casing 22 may be formed of substances such as resin or metal.

Moreover, the body portion 23 has a first groove 23a, and the movable portion 24 has a second groove 24a. When the movable portion 24 is closed as illustrated in FIG. 7, the grooves 23a and 24a form a through hole 25 passing through the casing 22, and the above-described cable 21 is clamped in the through hole 25.

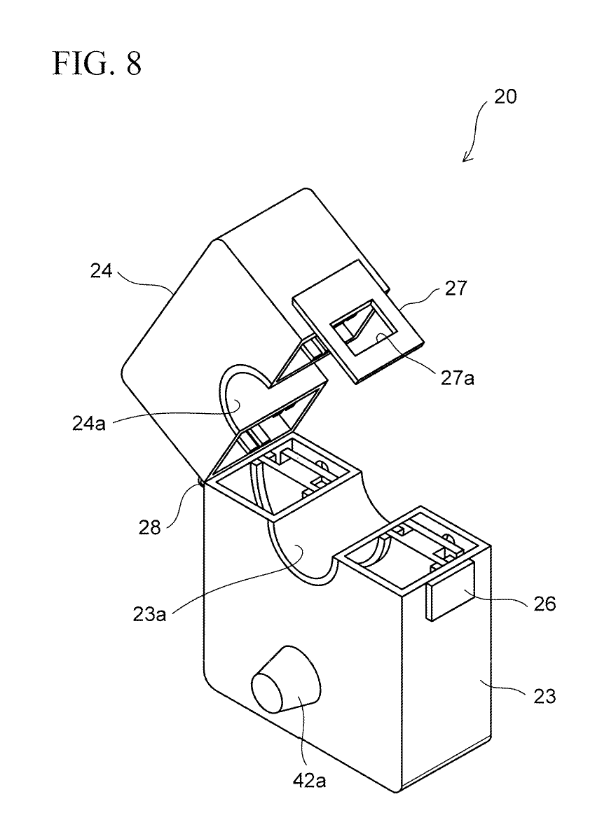

FIG. 8 is an external view illustrating the current measurement device 20 with the movable portion 24 open.

As illustrated in FIG. 8, the body portion 23 and the movable portion 24 are connected to each other with a hinge 28. Moreover, the movable portion 24 has a latch piece 27 on a side surface thereof. The fitting of an opening 27a of the latch piece 27 to a protrusion 26 of the body portion 23 causes the movable portion 24 to be locked on the body portion 23.

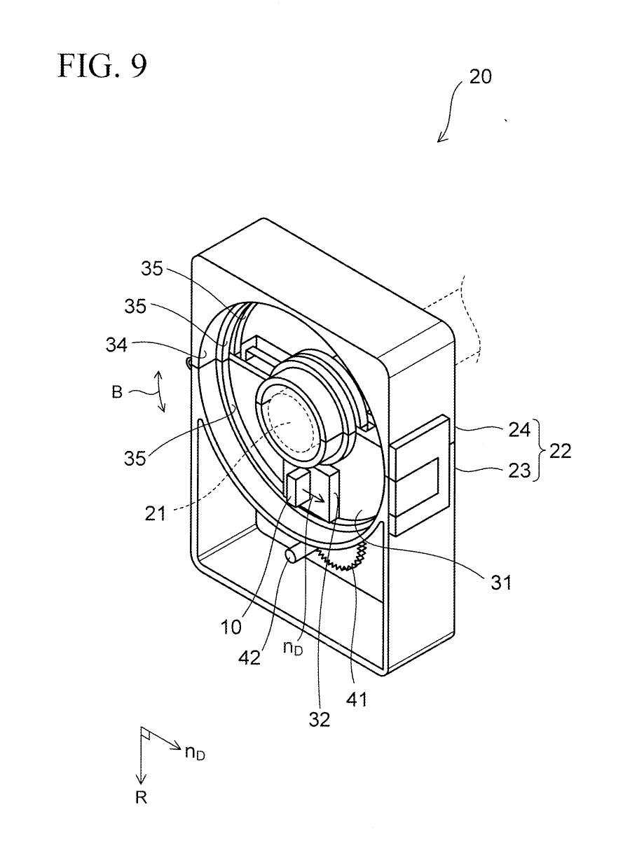

FIG. 9 is a cross-sectional view of the current measurement device 20.

As illustrated in FIG. 9, a rotating plate 31 is provided in the casing 22. The rotating plate 31 is approximately semicircular, and may rotate around the cable 21 in the directions indicated by arrow B. The material of the rotating plate 31 may be any of resin and metal.

Further, a circuit board 32 provided with the magnetic sensor 10 is fastened to a main surface of the rotating plate 31.

The magnetic sensor 10 is intended to measure an alternating current I flowing through the cable 21. Any one of a GMR element, an MI element, and a Hall element may be used as the magnetic sensor 10. Among these, a Hall element has low sensitivity in detecting a magnetic field, and therefore it is preferable to use a Hall IC including a Hall element and an amplifier for amplifying an output from the Hall element as the magnetic sensor 10.

In the present embodiment, since the magnetic sensor 10 is fastened onto the rotating plate 31 as described above, the magnetic sensor 10 is movable along a periphery of the cable 21, and the magnetic sensor 10 may be moved to a position at which the sensing direction n_{D} becomes parallel to the magnetic field H as illustrated in FIG. 6.

Note that the sensing direction n_{D} of the magnetic sensor 10 is not particularly limited. In this example, the sensing direction n_{D} is directed in a direction perpendicular to a vector R which points from the center of the cable 21 to the magnetic sensor 10.

Moreover, a cylindrical surface 34 is provided on an inner surface of the casing 22 to surround the cable 21. Further, annular guides 35 are provided on the cylindrical surface 34.

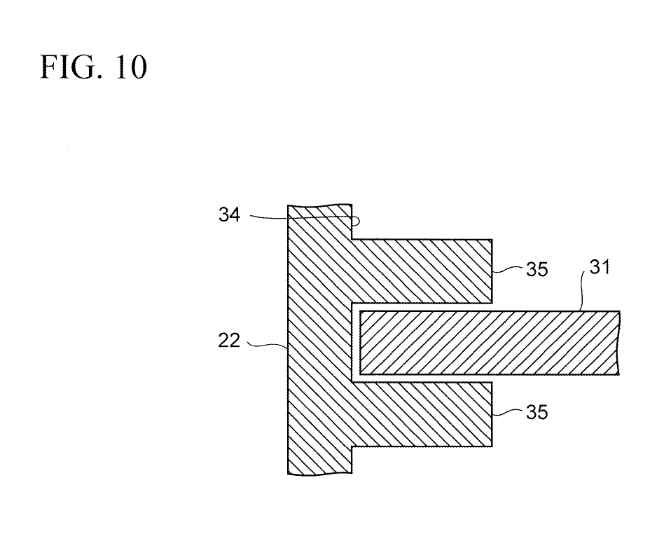

FIG. 10 is a cross-sectional view of the guides 35 and surroundings thereof.

As illustrated in FIG. 10, in this example, two guides 35 are provided to hold the rotating plate 31 therebetween from top and bottom. Further, the fitting of the guides 35 to a peripheral edge of the above-described rotating plate 31 reduces the rattle of the rotating plate and increases the accuracy of measurement of the alternating current I with the magnetic sensor 10.

Note that the cross-sectional shape of the guides 35 is not limited to this.

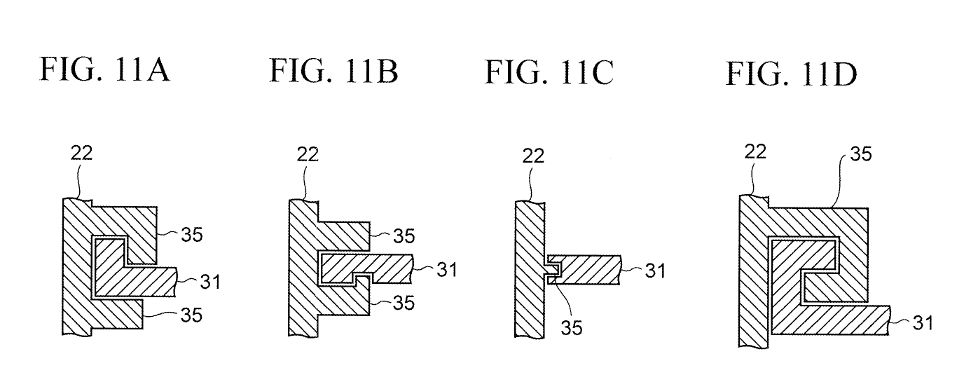

FIGS. 11A to 11D are cross-sectional views illustrating other examples of the cross-sectional shape of the guide 35. The guide 35 having any of the shapes of FIGS. 11A to 11D may reduce the rattle of the rotating plate 31.

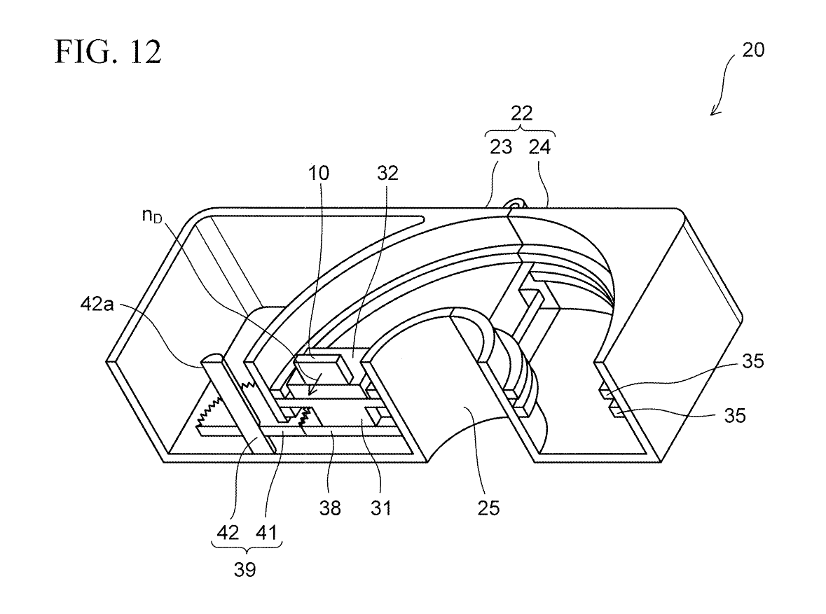

FIG. 12 is another cross-sectional view of the current measurement device 20.

As illustrated in FIG. 12, a first gear 38 is fixed to the above-described rotating plate 31. The first gear 38 is semicircular similarly to the rotating plate 31, and may rotate about the through hole 25 together with the rotating plate 31.

Moreover, examples of the material of the first gear 38 include resin and metal.

Further, a driving portion 39 is provided beside the rotating plate 31 to rotationally drive the above-described rotating plate 31.

The driving portion 39 includes a second gear 41 gearing with the first gear 38 and a shaft 42 provided upright at the center of the second gear 41.

A tip portion 42a of the shaft 42 is led to the outside of the casing 22, and is used as a knob for turning the shaft 42 by an operator.

Thus, the turning of the tip portion 42a by an operator causes the magnetic sensor 10 to rotate around the cable 21, and it becomes easy to search for the position of the magnetic sensor 10 at which the magnetic field H and the sensing direction n_{D} become parallel.

Note that the shaft 42 may be automatically turned using a motor or the like instead of manually turned as described above. Further, the materials of the second gear 41 and the shaft 42 are also not particularly limited. The second gear 41 and the shaft 42 may be formed of resin or metal.

Moreover, when the movable portion 24 is closed as illustrated in FIG. 12, respective insides of the body portion 23 and the movable portion 24 communicate with each other, and the rotating plate 31 and the magnetic sensor 10 is capable of entering and exiting each of the body portion and the movable portion 24 along a periphery of the through hole 25.

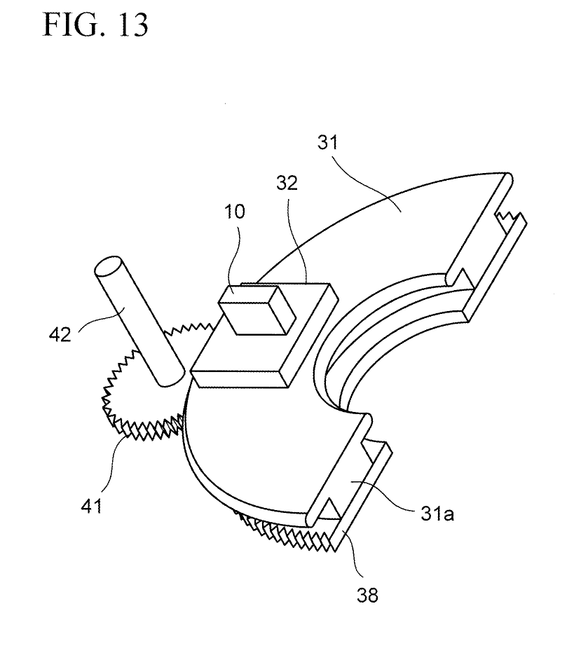

FIG. 13 is a general perspective view illustrating the above-described rotating plate 31 and the first gear 38.

As illustrated in FIG. 13, the rotating plate 31 has a thick-walled portion 31a protruding toward the first gear 38, and the first gear 38 is fastened to the thick-walled portion 31a with adhesive or the like.

Moreover, since the first gear 38 is semicircular as described previously, the range of movement of the magnetic sensor 10 is an angular range of approximately 180° about the through hole 25 (see FIG. 12).

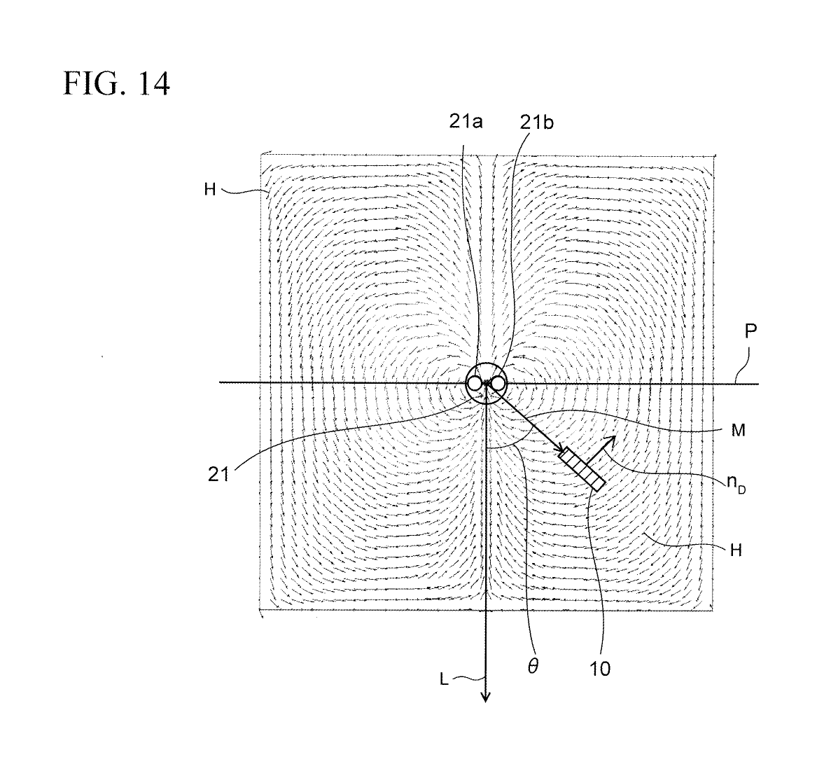

FIG. 14 is a schematic diagram illustrating the positional relationship between the magnetic field H generated around the cable 21 and the magnetic sensor 10.

In the example of FIG. 14, a reference line L is set at a lower limit of the angular range of approximately 180° in which the magnetic sensor 10 is movable, and a traveled angle θ of the magnetic sensor 10 is defined as the angle between a direction M directed from the center of the cable 21 to the magnetic sensor 10 and the reference direction L. In this case, the magnetic sensor 10 is movable within the range of 0°≦θ≦180°.

Note that though the reference direction L is perpendicular to an assumed plane P containing the two wires 21a and 21b in FIG. 14, the reference direction L varies according to the positional relationship between the cable 21 and the casing 22.

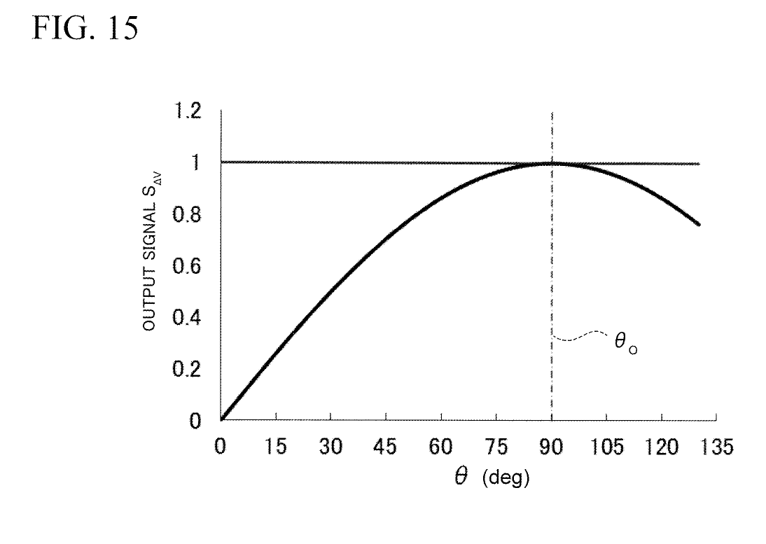

FIG. 15 is a graph illustrating the relationship between the above-described traveled angle θ and the magnitude of the output signal SΔ_{V} from the magnetic sensor 10. Note that the output signal SΔ_{V} is normalized with a largest value thereof.

Moreover, this graph is based on the assumption that the reference direction L is perpendicular to the assumed plane P as illustrated in FIG. 14.

As illustrated in FIG. 15, the output signal SΔ_{V} becomes minimum when the traveled angle θ is 0°. This is because the sensing direction n_{D} of the magnetic sensor 10 becomes perpendicular to the direction of the magnetic field H and therefore the magnetic sensor 10 does not detect the magnetic field H.

Meanwhile, when the traveled angle θ becomes 90°, the sensing direction n_{D} and the magnetic field H become parallel, and the output signal SΔ_{V} from the magnetic sensor 10 becomes maximum.

Accordingly, by checking whether or not the output signal SΔ_{V} is maximum, a determination may be made as to whether or not the sensing direction n_{D} is parallel to the magnetic field H.

Note that the reference direction L defines the lower limit of the angular range of approximately 180° in which the magnetic sensor 10 is movable as described previously. Meanwhile, the assumed plane P is defined as the plane in which the two wires 21a and 21b are located. Accordingly, the angle between the reference direction L and the assumed plane P varies according to the positional relationship between the cable 21 and the casing 22, and generally does not become 90°. Similarly, it is not always true that the output signal SΔ_{V} becomes maximum when the traveled angle θ is 90°.

The traveled angle θ at which the output signal SΔ_{V} becomes maximum will hereinafter be referred to as a target angle θ₀. This target angle θ₀ is equal to the traveled angle θ at which the sensing direction n_{D} and the magnetic field H become parallel.

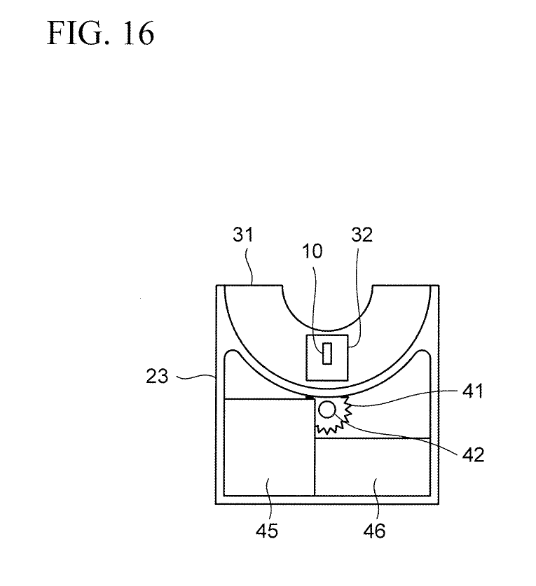

FIG. 16 is a cross-sectional view illustrating the inside of the body portion 23.

As illustrated in FIG. 16, the body portion 23 contains a measuring unit 45 and a battery 46. The battery 46 is, for example, a dry battery, and supplies power to the magnetic sensor 10 and the measuring unit 45.

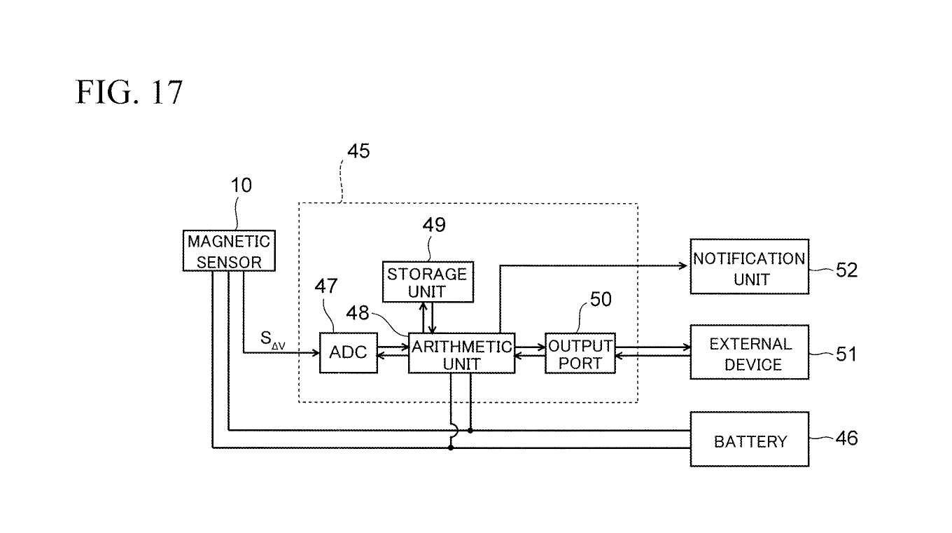

FIG. 17 is a functional block diagram of the measuring unit 45.

As illustrated in FIG. 17, the measuring unit 45 includes an AD converter 47, an arithmetic unit 48, the storage unit 49, and an output port 50.

Among these, the AD converter 47 receives the output signal SΔ_{V} from the magnetic sensor 10. Since the current I flowing through the cable 21 is an alternating current, the magnetic field H generated by the current I is an alternating magnetic field, and the output signal SΔ_{V} is an alternating voltage. The output signal SΔ_{V} is converted to a direct voltage in the AD converter 47 and outputted to the arithmetic unit 48.

The arithmetic unit 48 is, for example, an MPU (Micro Processing Unit), and calculates a current value i of the current I based on the above-described output signal SΔ_{V}. In the following, it is assumed that the arithmetic unit 48 calculates the effective value of the current I as the current value i.

A method of calculating the current value i is not particularly limited. The intensity of the magnetic field H is approximately proportional to the current value i, and the output signal SΔ_{V} is approximately proportional to the intensity of the magnetic field H. Therefore, the output signal SΔ_{V} is approximately proportional to the current value i. Accordingly, the arithmetic unit 48 may calculate the current value i by finding a proportionality factor α between the output signal SΔ_{V} and the current value i in advance and multiplying the output signal SΔ_{V} by the proportionality factor α.

Note that as explained with reference to FIG. 15, the output signal SΔ_{V} depends on the traveled angle θ. To accurately calculate the current value i, it is preferable to make the output signal SΔ_{V} as large as possible. For this purpose, the magnetic sensor 10 is preferably positioned at the target angle θ₀ at which the output signal SΔ_{V} becomes highest. Accordingly, it is preferable that the value at the target angle θ₀ is employed as the above-described proportionality factor α, and that the current value i is calculated at the target angle θ₀.

Moreover, there is a one-to-one relationship between the output signal SΔ_{V} and the current value i. Accordingly, the arithmetic unit 48 may find the current value i corresponding to the output signal SΔ_{V} by referring to an appropriate table on which the relationship is stored in advance.

The current value i calculated as described above is stored in the storage unit 49. The storage unit 49 is, for example, a semiconductor memory. A DRAM (Dynamic Random Access Memory), a flash memory, an FeRAM (Ferroelectric Random Access Memory), or the like may be employed as the storage unit 49.

The output port 50 converts the current value i calculated by the arithmetic unit 48 into an appropriate communication protocol and outputs the converted current value i to an external device 51.

The external device 51 is a device used to manage the current value i by an operator. One example of the external device 51 is a personal computer.

Moreover, a notification unit 52 is connected to the above-described the arithmetic unit 48. The notification unit 52 is, for example, a buzzer, an LED (Light Emitting Diode), an LCD (Liquid Crystal Display), or the like, and helps an operator determine whether or not the magnetic sensor 10 is positioned at the target angle θ₀ at which the magnetic field H and the sensing direction n_{D} become parallel.

Next, a method of measuring a current using this current measurement device 20 will be described.

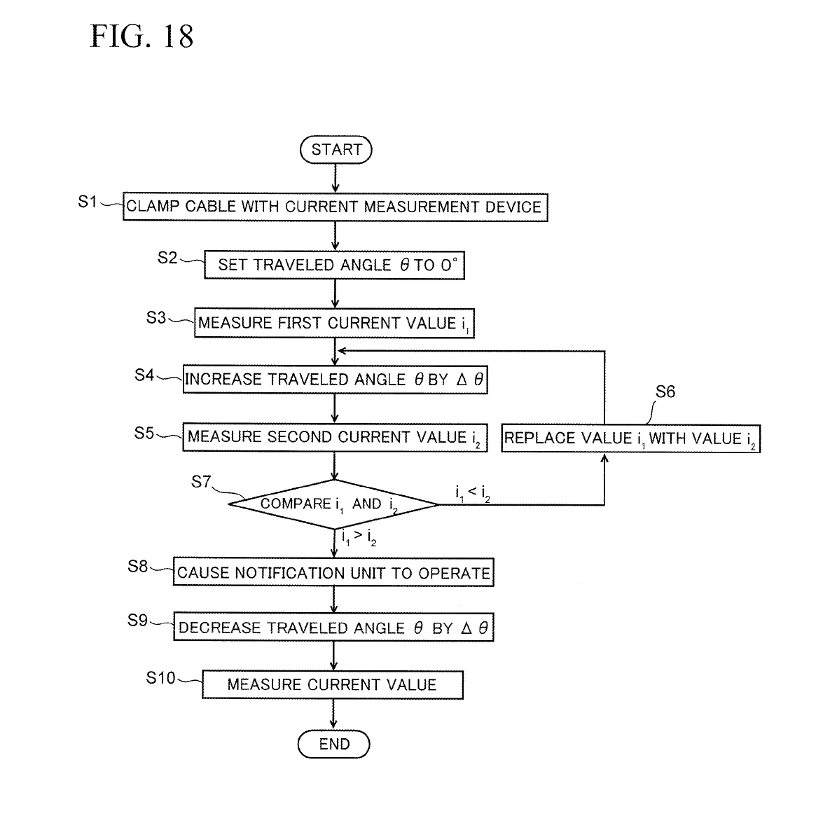

FIG. 18 is a flowchart illustrating a current measurement method according to the present embodiment.

First, in step S1, an operator clamps the cable 21 with the current measurement device 20, thus fixing the cable 21 to the casing 22.

Next, in step S2, the operator turns the tip portion 42a of the shaft 42 to set the aforementioned traveled angle θ (see FIG. 14) to 0°.

Subsequently, in step S3, a first current value i₁ of the current I flowing through the cable 21 is measured with the traveled angle θ kept at 0°. The first current value i₁ is calculated based on the output signal SΔ_{V} by the arithmetic unit 48 as described previously.

Further, the first current value i₁ is stored in the storage unit 49 under the control of the arithmetic unit 48.

Next, in step S4, the operator turns the tip portion 42a (see FIG. 12) of the shaft 42 to increase the aforementioned traveled angle θ by a predetermined angle A.

Subsequently, in step S5, a second current value i₂ of the current I flowing through the cable 21 is measured. The second current value i₂ is calculated based on the output signal SΔ_{V} by the arithmetic unit 48 as in step S3.

Next, the process goes to step S7. In step S7, the arithmetic unit 48 determines the relation of magnitude between the first current value i₁ stored in the storage unit 49 and the second current value i₂.

If the arithmetic unit 48 determines that i₁<i₂, the traveled angle θ has not reached the target angle θ₀ yet, and there is a possibility that the current value may further increase by further increasing the traveled angle θ.

Accordingly, in that case, the first current value i₁ in the storage unit 49 is replaced by the second current value i₂ in step S6, and then the process goes back to step S4.

Meanwhile, if the arithmetic unit 48 determines that i₁>i₂ in step S7, the arithmetic unit 48 determines that the current value changes from increasing to decreasing. In the case where the traveled angle θ is monotonically increased as illustrated in FIG. 15, when the current value changes from increasing to decreasing, a determination may be made that the traveled angle θ exceeds the target angle θ₀.

Accordingly, in that case, the process goes to step S8, and the arithmetic unit 48 causes the notification unit to operate. There is no limitation as to where the notification unit 52 is provided.

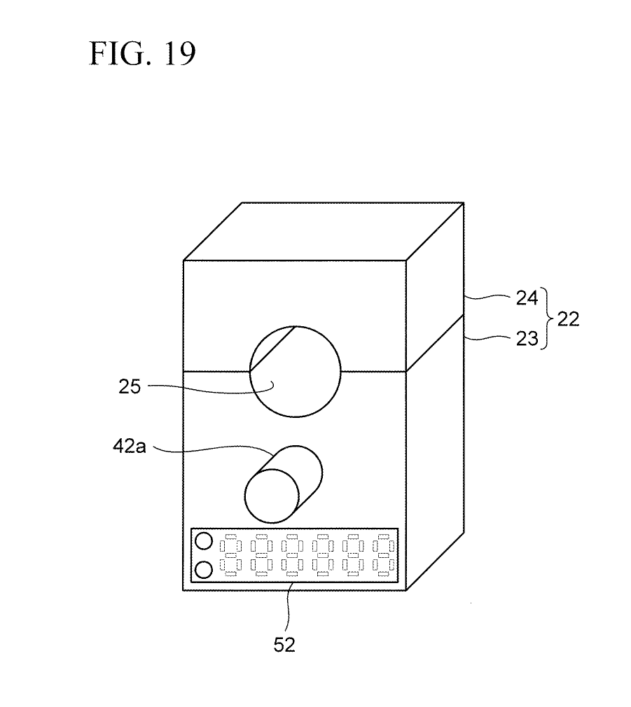

FIG. 19 is a perspective view of the current measurement device 20 in which the notification unit 52 is provided on the casing 22. The notification unit 52 is any one of a buzzer, an LED, and an LCD as described previously, and is configured to notify an operator that the traveled angle θ has exceeded the target angle θ₀ by sound or light.

Next, the process goes to step S9. In this step, the operator notified by the notification unit 52 decreases the traveled angle θ by a predetermined angle Δθ to return the traveled angle θ to the vicinity of the target angle θ₀. Note that the traveled angle θ may be decreased as described above by turning the tip portion 42a of the shaft 42 in a direction opposite to that in step S4.

Further, in step S10, in a state in which the traveled angle θ is in the vicinity of the target angle θ₀ as described above, the current value i of the current I flowing through the cable 21 is measured again. This current value i is calculated based on the output signal SΔ_{V} by the arithmetic unit 48, and is a largest value of the current value i for the case where a minimum unit of the traveled angle θ is A. Further, the arithmetic unit 48 determines the current value i at this time to be the current value of the current I flowing through the cable 21.

This is the end of basic steps of the current measurement method according to the present embodiment.

According to the above-described present embodiment, the magnetic sensor 10 is provided which is movable along the periphery of the cable 21. Accordingly, the magnetic sensor 10 may be moved to the target angle θ₀ at which the output signal SΔ_{V} outputted from the magnetic sensor 10 according to the magnetic field H generated around the cable 21 becomes maximum. As a result, the current value of the current I flowing through the cable 21 may be easily measured based on the large output signal SΔ_{V} outputted at the target angle θ₀ by the magnetic sensor 10.

This eliminates the operation for processing the cable 21 and pulling out one wire, unlike the case where a measurement is performed using a clamp-type current measurement device. Accordingly, a burden on an operator may be reduced, and the client's equipment is not damaged.

Further, even in the case where the cable 21 has an insulating sheath and it is difficult to identify the arrangement of the two wires 21a and 21b from the appearance thereof, the target angle θ₀ at which the output signal SΔ_{V} becomes maximum may be detected by moving the magnetic sensor 10 along the periphery of the cable 21 as described above.

### Second Embodiment

In the present embodiment, a structure will be described which is useful in fixing the cable 21 to the casing 22.

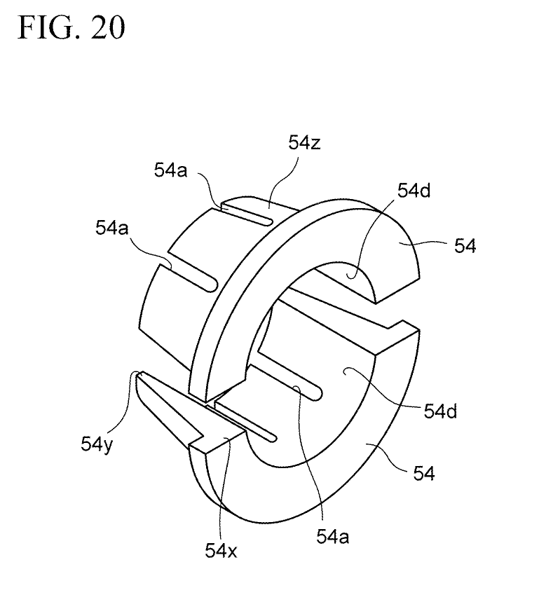

FIG. 20 is a perspective view of spacers 54 used in the present embodiment.

The spacer 54 is made by forming metal or resin into an approximately semicylindrical shape, and the two spacers 54 are used in combination. Further, each of the spacers 54 includes an outer circumferential surface 54z and an inner circumferential surface 54d which comes in tight contact with an outer surface of the cable 21 (see FIG. 7).

The outer circumferential surface 54z has a tapered shape such that the wall thickness decreases from a rear end 54x toward a forward end 54y.

Further, the spacer 54 has a plurality of slits 54a. This facilitates the deformation of the spacer 54.

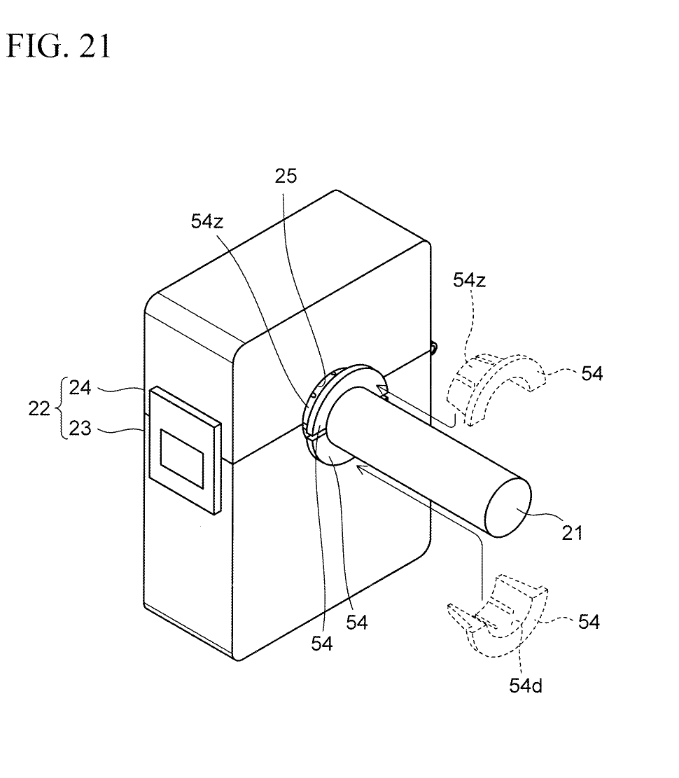

FIG. 21 is a perspective view for explaining how to use the spacers 54.

When the spacers 54 are used, the outer circumferential surface 54z is fitted into the through hole 25 with the inner circumferential surface 54d held in tight contact with the outer surface of the cable 21 to insert the spacers 54 into a gap between the through hole 25 and the cable 21. Thus, the gap is filled with the spacers 54, and the cable 21 may be fixed to the casing 22. As a result, the cable 21 may be prevented from moving within the through hole 25, and the positional relationship between the cable 21 and the magnetic sensor 10 may be fixed.

Further, since the outer circumferential surface 54z has a tapered shape as described previously, the thin-walled forward end 54y may be easily inserted into the through hole 25, and the thick-walled rear end 54x increases the fastening force of the spacer 54 to enable the cable 21 to be firmly fixed to the casing 22.

Moreover, the slits 54a facilitates the deformation of the spacer 54 and further increases the fastening force of the spacer 54.

The structure of the spacer 54 is not limited to the above-described one.

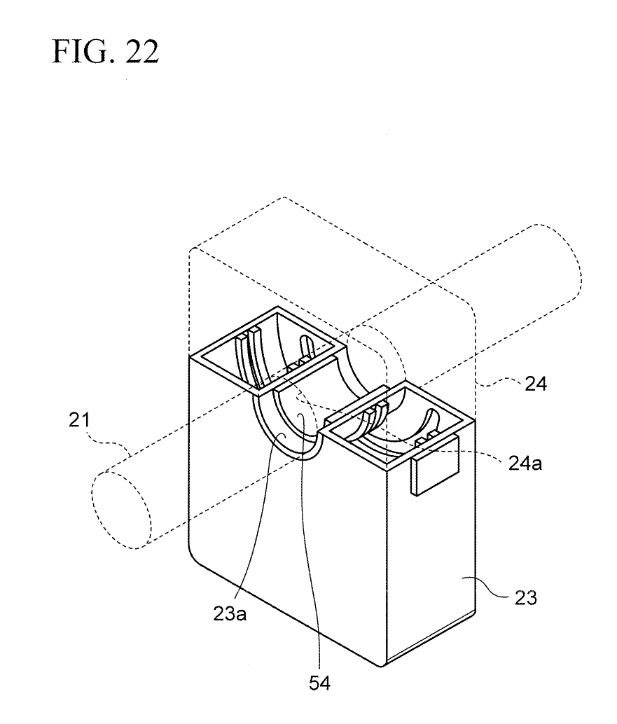

FIG. 22 is a perspective view for explaining a spacer according to another example of the present embodiment.

In this example, an elastic member such as a rubber sheet is used as the spacer 54, and the spacer 54 is fastened to the second groove 23a with adhesive or the like. This structure also enables the cable 21 to be fixed to the casing 22 with the spacer 54.

Note that an elastic spacer 54 such as described above may be provided in the second groove 24a of the movable portion 24.

### Third Embodiment

In the present embodiment, the cable 21 is fixed to the casing 22 with a structure different from that of the second embodiment.

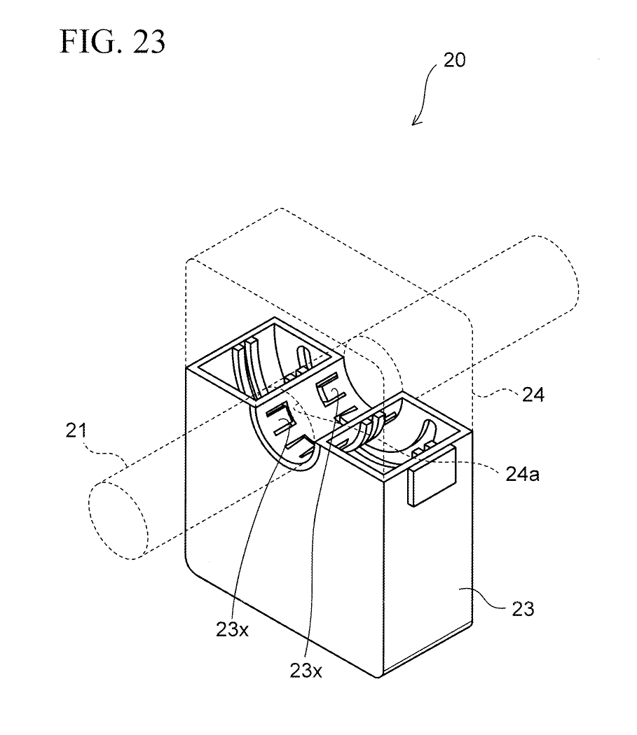

FIG. 23 is a perspective view of the current measurement device 20 according to the present embodiment.

In the present embodiment, protruding portions 23x are provided in the first groove 23a of the body portion 23. Thus, the cable 21 comes in contact with the protruding portions 23x when the movable portion 24 is closed, and the cable 21 may be fixed to the casing 22.

Note that protruding portions 23x such as described above may be provided in the second groove 24a of the movable portion 24.

### Fourth Embodiment

In the present embodiment, a current measurement device will be described in which the magnetic sensor 10 may be fixed at the target angle θ₀.

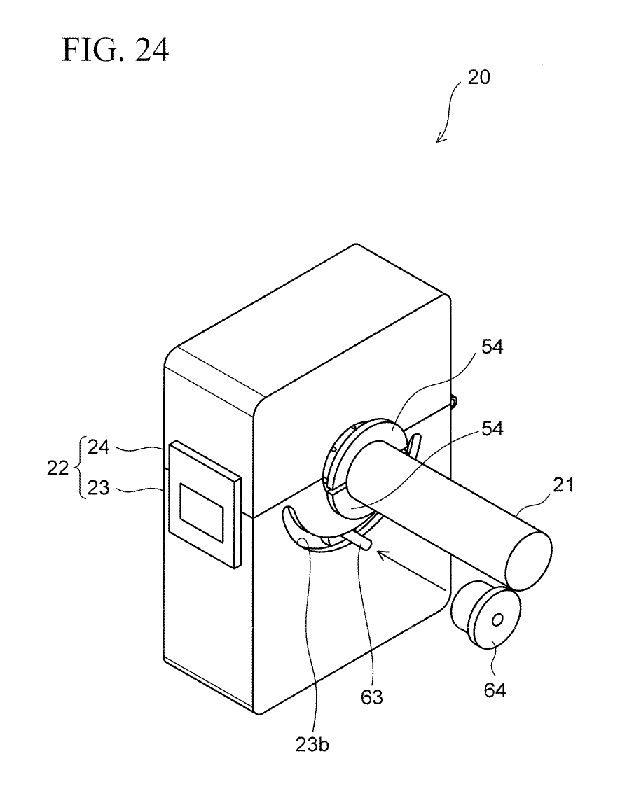

FIG. 24 is a perspective view of the current measurement device 20 according to the present embodiment.

As illustrated in FIG. 24, in the present embodiment, a long and narrow hole 23b having the shape of an arc around the cable 21 is formed in the body portion 23, and a pin 63 is extended out of the hole 23b.

Moreover, an unillustrated thread is formed on a surface of the pin 63, and a nut 64 is provided which is fitted to the thread.

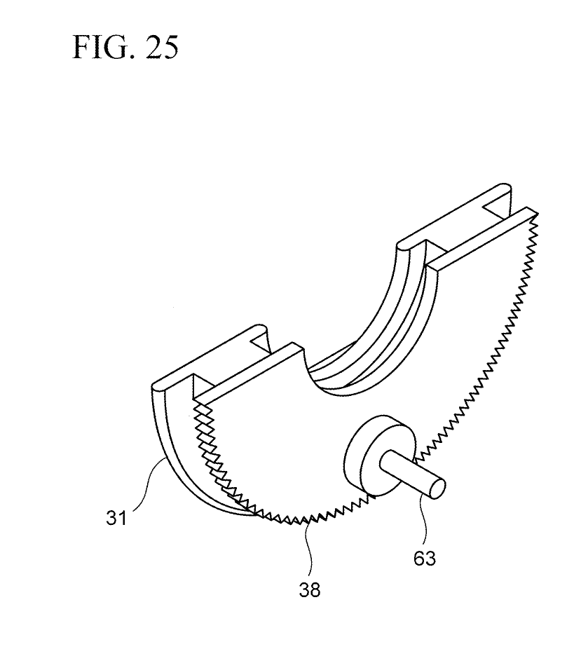

FIG. 25 is a perspective view of the rotating plate 31 according to the present embodiment.

As illustrated in FIG. 25, the aforementioned pin 63 is provided upright on the rotating plate 31 with the first gear 38 interposed therebetween.

Now, FIG. 24 is referred to again.

When the nut 64 is firmly screwed onto the pin 63, the nut 64 is pressed against a surface of the body portion 23, and the pin 63 is fixed to the body portion 23. In this way, the nut 64 is used as a fixing portion for fixing the pin 63 to the body portion 23. Thus, the rotating plate 31 is also fixed to the body portion 23.

This enables the magnetic sensor 10 to be fixed in the vicinity of the target angle θ₀, and may prevent the magnetic sensor 10 from deviating from the target angle θ₀.

### Fifth Embodiment

In the present embodiment, the rotating plate 31 is fixed to the body portion 23 with a structure different from that of the fourth embodiment.

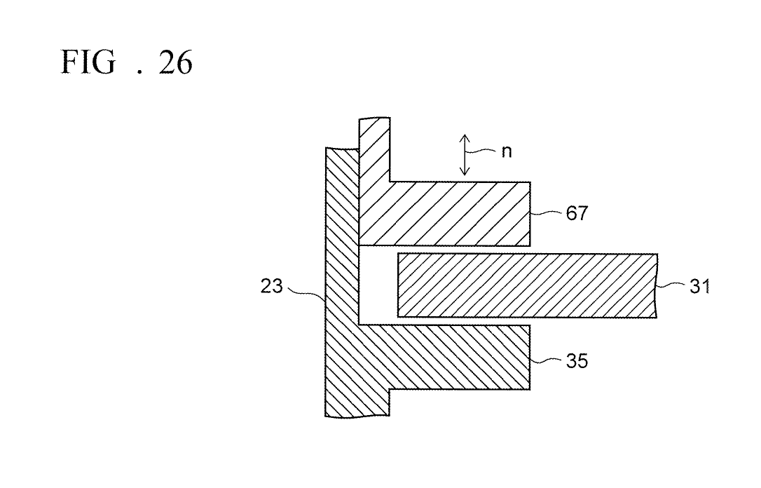

FIG. 26 is a cross-sectional view illustrating a peripheral edge of the rotating plate 31 according to the present embodiment and the vicinity thereof.

As illustrated in FIG. 26, in the present embodiment, a braking portion 67 facing the guide 35 is provided.

The braking portion 67 is movable in the normal direction n of the rotating plate 31, and presses the peripheral edge of the rotating plate 31 against the guide 35. This brakes the movement of the rotating plate 31, may fix the rotating plate 31 to the body portion 23, and may prevent the magnetic sensor 10 from deviating from the target angle θ₀.

### Sixth Embodiment

In the present embodiment, the rotating plate 31 is fixed to the body portion 23 with a structure different from those of the fourth and fifth embodiments.

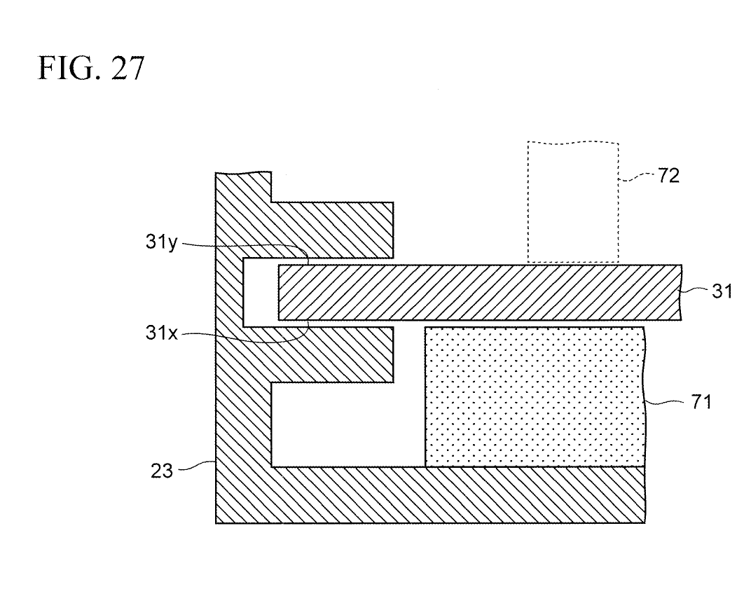

FIG. 27 is a cross-sectional view illustrating the peripheral edge of the rotating plate 31 according to the present embodiment and the vicinity thereof.

As illustrated in FIG. 27, in the present embodiment, an elastic member 71 such as a rubber sheet which faces one main surface 31x of the rotating plate 31 is fixed to an inner surface of the body portion 23.

Further, a braking portion 72 is provided on another main surface 31y of the rotating plate 31. The braking portion 72 presses the other main surface 31y of the rotating plate 31 to press the one main surface 31x of the rotating plate 31 against the elastic member 71. This brakes the movement of the rotating plate 31, may fix the rotating plate 31 to the body portion 23, and may prevent the magnetic sensor 10 from deviating from the target angle θ₀.

### Seventh Embodiment

In the first embodiment, the measuring unit 45 and the battery 46 are incorporated in the body portion 23, which is part of the casing 22, as illustrated in FIG. 16.

Meanwhile, in the present embodiment, the measuring unit 45 and the battery 46 are provided outside the casing 22.

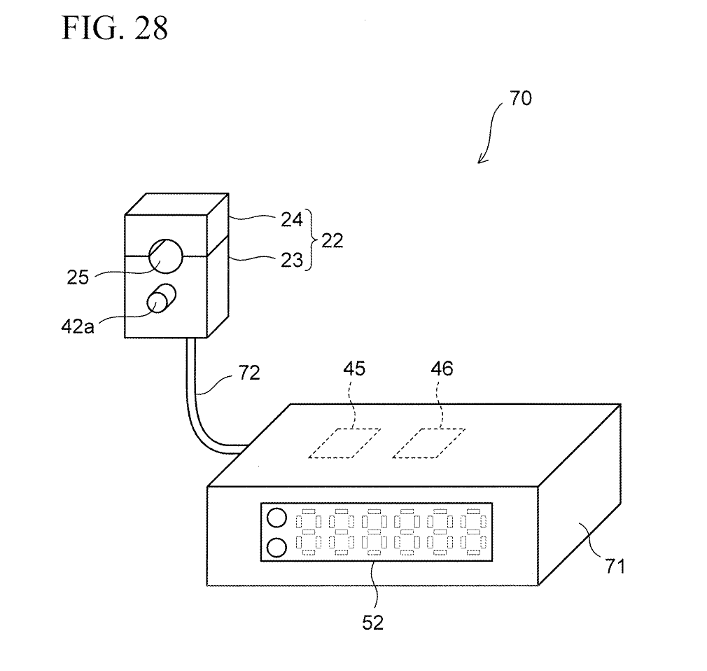

FIG. 28 is a perspective view of a current measurement device 70 according to the present embodiment. Note that in FIG. 28, the same components as described in the first embodiment will be denoted by the same reference signs as in the first embodiment, and will not be further explained below.

This current measurement device 70 includes the casing 22, a measuring unit 71, and a connecting cable 72 for connecting the foregoing components.

The measuring unit 71 contains the measuring unit 45 and the battery 46 illustrated in FIG. 16. Further, the notification unit 52 (see FIG. 19) described in the first embodiment is provided on a surface of the measuring unit 71.

Further, the battery 46 supplies power to the casing 22 through the connecting cable 72, and an output signal from the magnetic sensor 10 (see FIG. 9) in the casing 22 is sent to the measuring unit 45 through the connecting cable 72.

Thus, while the measuring unit 71 is placed on a floor of a room, a current measurement may be performed on each of various cables 21 in the room by clamping the cable 21 with the casing 22. Further, a long-term measurement may be stably performed on an identical cable 21 by installing the measuring unit 71 in the room.

Also, in the case where the function of comparing current values is given to the arithmetic unit 45 in the measuring unit 71, current values measured at different times or places may be compared, and an operator may obtain how current values vary depending on time and place.

(Modifications)

Hereinafter, a description will be made of modifications of the rotating plate 31 of the first embodiment illustrated in FIG. 13.

(First Modification)

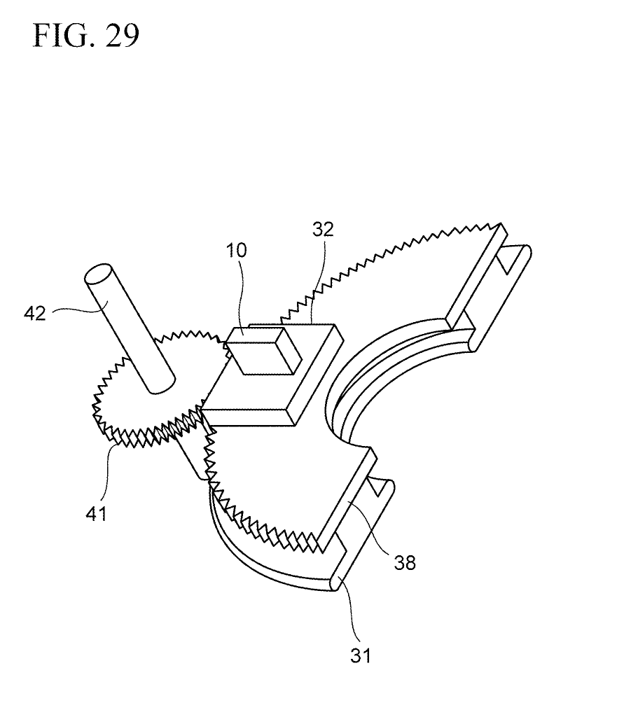

FIG. 29 is a perspective view of the rotating plate 31 according to a first modification.

In this modification, compared to the case of FIG. 13, the rotating plate 31 is vertically reversed, and the magnetic sensor 10 is fixed to the rotating plate 31 with the first gear 38 interposed therebetween.

(Second Modification)

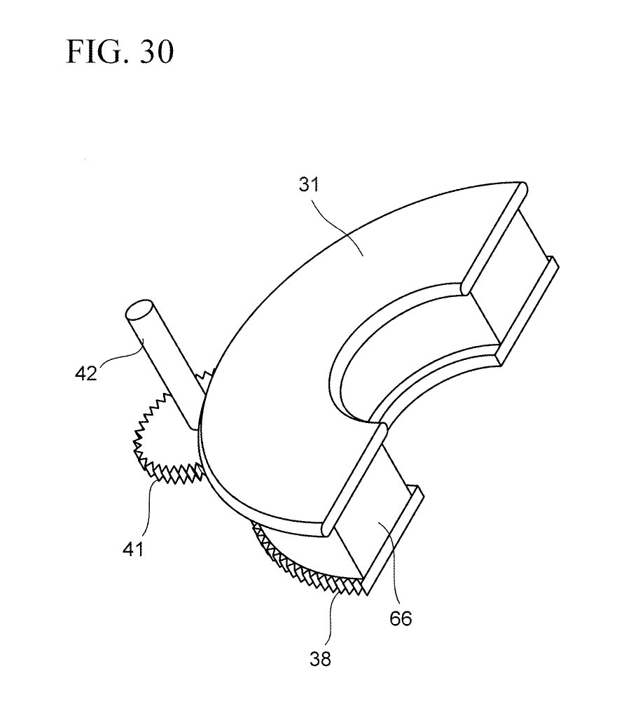

FIG. 30 is a perspective view of the rotating plate 31 according to a second modification.

In this modification, the rotating plate 31 and the first gear 38 are connected with a hollow container 66 in the shape of a half doughnut interposed therebetween.

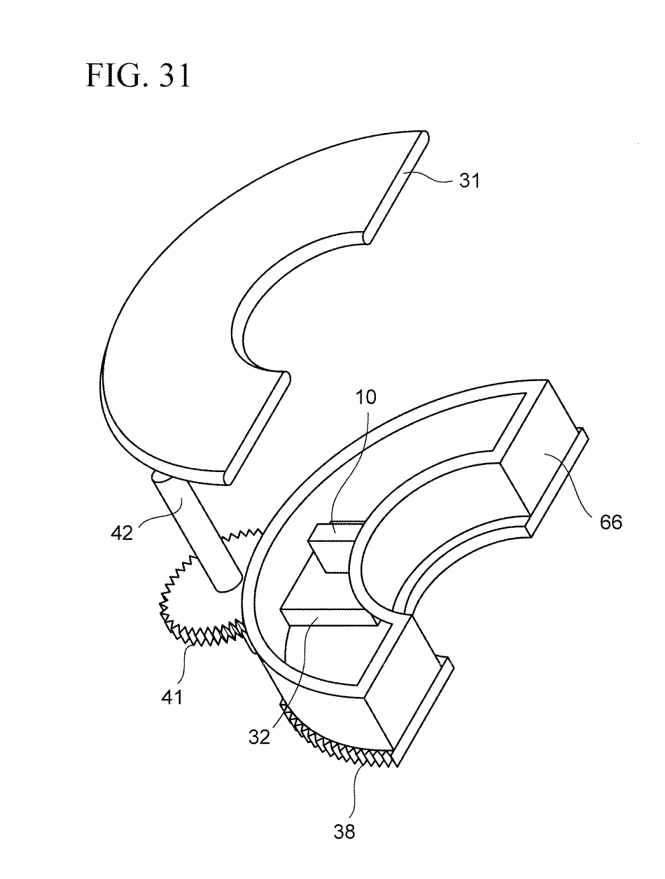

FIG. 31 is a perspective view in which the rotating plate 31 is removed from the hollow container 66.

As illustrated in FIG. 31, the hollow container 66 houses the aforementioned circuit board 32 and the magnetic sensor 10.

(Third Modification)

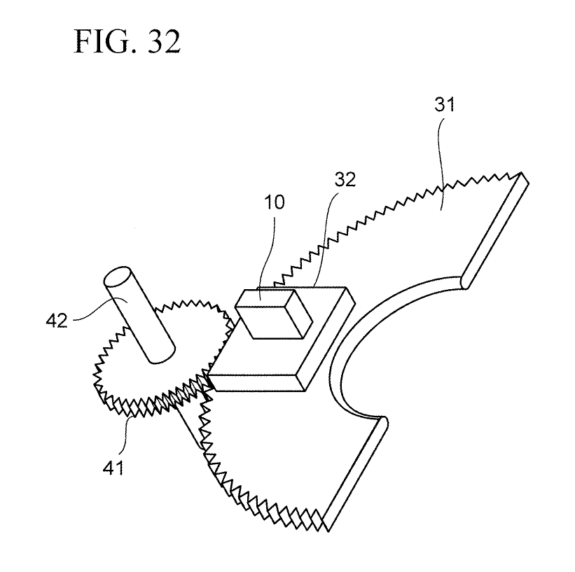

FIG. 32 is a perspective view of the rotating plate 31 according to a third modification.

In this modification, gear teeth which gear with the second gear 41 are formed on an outer circumference of the rotating plate 31. This eliminates the use of the first gear 38. Thus, the number of components may be reduced, and assembly work may be simplified.

All examples and conditional language recited herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A current measurement device comprising:
a casing configured to surround a cable; and
a magnetic sensor configured to be movable along a periphery of the cable within the casing and to output an output signal varying according to a current value of a current flowing through the cable.

2. The current measurement device according to claim 1, wherein
the casing includes:
a body portion; and
a movable portion connected to the body portion to be openable and closable, wherein
the cable is clamped between the body portion and the movable portion when the movable portion is closed.

3. The current measurement device according to claim 2, wherein a first groove is formed in the body portion, a second groove is formed in the movable portion, and the first groove and the second groove form a through hole configured to clamp the cable when the movable portion is closed.

4. The current measurement device according to claim 3, wherein a protruding portion configured to come in contact with the cable is provided in at least one of the first groove and the second groove.

5. The current measurement device according to claim 3, further comprising:
a spacer configured to fill a gap between the through hole and the cable.

6. The current measurement device according to claim 5, wherein the spacer has a semicylindrical shape and comprises an outer circumferential surface configured to fit into the through hole and an inner circumferential surface configured to come in contact with an outer surface of the cable.

7. The current measurement device according to claim 5, wherein the spacer is an elastic member.

8. The current measurement device according to claim 2, wherein when the movable portion is closed, respective insides of the body portion and the movable portion communicate with each other, and the magnetic sensor is capable of entering and exiting each of the body portion and the movable portion along the periphery of the cable.

9. The current measurement device according to claim 1, further comprising:
a rotating plate capable of rotating about the cable within the casing, the rotating plate having the magnetic sensor fixed thereto; and
a driving portion configured to rotationally drive the rotating plate.

10. The current measurement device according to claim 9, wherein a guide configured to fit to a peripheral edge of the rotating plate is provided on an inner surface of the casing.

11. The current measurement device according to claim 10, further comprising:
a braking portion configured to press the peripheral edge of the rotating plate against the guide to brake movement of the rotating plate.

12. The current measurement device according to claim 9, further comprising:
an elastic member provided on an inner surface of the casing to face one main surface of the rotating plate; and
a braking portion configured to press another main surface of the rotating plate to press the one main surface against the elastic member and brake movement of the rotating plate.

13. The current measurement device according to claim 9, further comprising:
a pin provided upright on the rotating plate,
wherein a hole having a shape of an arc around the cable is formed in the casing, the pin being extended out of the hole, and
a fixing portion configured to fix the pin to the body portion is provided on a tip portion of the pin.

14. The current measurement device according to claim 1, further comprising:
an arithmetic unit configured to calculate the current value based on the output signal,
wherein the arithmetic unit identifies a largest value of the current value obtained when the magnetic sensor is moved along the periphery of the cable as the current value of the current flowing through the cable.

15. The current measurement device according to claim 14, wherein
the arithmetic unit determines whether or not the current value is changed from increasing to decreasing when the current value is measured while the magnetic sensor is being moved along the periphery of the cable, and
the current measurement device further comprises a notification unit configured to notify an outside that the current value is changed from increasing to decreasing when the current value is changed from increasing to decreasing.

16. A current measurement method comprising:
while moving a magnetic sensor configured to output an output signal varying according to a current value of a current flowing through a cable along a periphery of the cable, measuring the current value with the magnetic sensor; and
determining a largest value of the current value around the cable to be the current value.

17. The current measurement method according to claim 16, further comprising:
fixing the cable to a casing,
wherein the measuring of the current value with the magnetic sensor is performed by moving the magnetic sensor within the casing.

18. The current measurement method according to claim 17, wherein the fixing of the cable to the casing is performed by clamping the cable with a body portion and a movable portion of the casing.

19. The current measurement method according to claim 16, further comprising:
notifying an outside that the current value is changed from increasing to decreasing when moving the magnetic sensor along the periphery of the cable causes the current value to change from increasing to decreasing.
